(19) United States
(12) Patent Application Publication
(10) Pub. No.: US 2025/0068574 A1
(43) Pub. Date: Feb. 27, 2025

(54) EFFICIENCY MODE IN A MEMORY SYSTEM

(71) Applicant: QUALCOMM Incorporated, San Diego, CA (US)

(72) Inventors: Jungwon Suh, San Diego, CA (US); Pankaj Deshmukh, San Diego, CA (US); Subbarao Palacharla, San Diego, CA (US); Alain Artieri, Saint Martin D'Heres (FR)

(21) Appl. No.: 18/454,658

(22) Filed: Aug. 23, 2023

(51) Int. Cl. G06F 13/16; G06F 1/3234; G06F 13/28

(52) U.S. Cl. CPC G06F 13/1689; G06F 1/3275

(57) ABSTRACT

This disclosure provides systems, methods, and devices for memory systems that support an efficient mode for reducing power consumption in a memory module while maintaining access to all contents of memory. In a first aspect, a method includes communicating, by a memory module, first data stored in a first plurality of banks to a host device through a first sub-channel in a first operating mode; communicating second data stored in the second plurality of banks to the host device through a second sub-channel in the first operating mode; receiving a command to enter a second operating mode; and communicating third data stored in the first plurality of banks and fourth data stored in the second plurality of banks to the host device through the first sub-channel in the second operating mode. Other aspects and features are also claimed and described.

### TECHNICAL FIELD

Aspects of the present disclosure relate generally to computer information systems, and more particularly, to memory systems for storing data. Some features may enable and provide improved memory capabilities for power-efficient memory access.

### INTRODUCTION

A computing device (e.g., a laptop, a mobile phone, etc.) may include one or several processors to perform various computing functions, such as telephony, wireless data access, and camera/video function, etc. A memory system is an important component of the computing device. The processors may be coupled to the memory system to perform the aforementioned computing functions. For example, the processors may fetch instructions from the memory system to perform the computing functions and/or to store within the memory system data involved in performing these computing functions.

### BRIEF SUMMARY OF SOME EXAMPLES

The following summarizes some aspects of the present disclosure to provide a basic understanding of the discussed technology. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

The handling, e.g., accessing, reading, writing, and the like, of data in a memory system consumes power. In mobile systems, reducing power consumption is particularly important to increase battery life. Power consumption is also important in other computing systems because, although battery life is not important, the computing system still has a maximum power rating. Quicker access to data, supported by high-power operation of the memory, may improve performance of the computing device. For example, quicker memory access may allow the computing device to display higher resolution video that uses higher data rates or may allow the computing device to render more realistic 3D scenes that use higher data rates. Quicker access to data for these applications also consumes more power. The memory interconnect in a computing device according to embodiments described herein provides flexibility to operate in low-power modes when quicker access is not needed while still providing the quicker access needed to support user operations. The dynamic capability for modifying bandwidth to memory may improve the user's experience operating with a mobile device by providing longer battery life while still supporting high-performance applications.

In some aspects, a memory die may include banks of memory cells organized for access through sub-channels. For example, a memory die may include a first plurality of memory banks and a second plurality of memory banks, with the first plurality of memory banks accessible through a first sub-channel and the second plurality of memory banks accessible through a second sub-channel. In an efficiency mode, the second sub-channel may be disabled and communications with the second plurality of memory banks redirected through the first sub-channel. In this manner, the bandwidth between the host device and the memory device may be dynamically controlled to match power consumption to a current data demand of the host device. The dynamic bandwidth control may be provided while still maintaining full access to the contents of both the first and second pluralities of memory banks.

These aspects may be embodied as a sequence of commands transmitted from a host to a memory system. The commands transmitted by the host may include commands to read capabilities from the memory system, set configurations in the memory system, read data at one or more specified addresses from the memory system, and/or write data at one or more specified addresses to the memory system.

An apparatus in accordance with at least one embodiment includes a memory system configured to communicate with a host. The memory system includes a memory array configured to store data. The memory system may include a memory controller configured to provide the data stored in the memory array to the host for further processing by the processor or other components of the host. The memory controller may also be configured to receive data from the host for storage in the memory array. In some embodiments, the memory array may be a plurality of volatile memory cells organized in rows and columns, such as in a dynamic random access memory (DRAM) or static random access memory (SRAM). In other embodiments, the memory array may be a plurality of non-volatile memory cells or a mixture of volatile and non-volatile memory cells. The memory array may be organized into banks, and the banks organized into groups of banks (also referred to as pluralities of banks). Each of the pluralities of banks may be associated with a sub-channel through a multiplexer and other control logic for processing signals received on the sub-channel and performing operations in the banks.

An apparatus in accordance with at least one embodiment includes a host device with a memory controller configured to communicate with a memory system to receive data stored in the memory array and/or to store data in the memory array. The host device memory controller may include logic circuitry for handling communications with different groups of banks through different sub-channels by maintaining a mapping of banks to sub-channels. A second mapping of banks to sub-channels may be used by the host device memory controller when an efficiency mode with reduced bandwidth is active. The host device may be, for example, a user equipment (UE) device such as a cellular phone, a tablet computing device, a personal computer, a server, a smart watch, or an internet of things (IoT) device.

In one aspect of the disclosure, an apparatus includes a memory interface coupled to a first plurality of banks and a second plurality of banks, the memory interface configured to couple the first plurality of banks and the second plurality of banks to a host device through a first sub-channel and a second sub-channel, and the memory interface configured to perform operations comprising communicating first data stored in the first plurality of banks to the host device through the first sub-channel in a first operating mode; communicating second data stored in the second plurality of banks to the host device through the second sub-channel in the first operating mode; receiving a command to enter a second operating (such as when the memory interface is configured to enter a second operating mode in response to a command, and/or wherein the command is a mode register write command); and communicating third data stored in the first plurality of banks and fourth data stored in the second plurality of banks to the host device through the first sub-channel in the second operating mode.

In another aspect of the disclosure, a method includes communicating, by a memory module through a memory interface, first data stored in a first plurality of banks to a host device through a first sub-channel in a first operating mode; communicating, by the memory module through the memory interface, second data stored in a second plurality of banks to the host device through a second sub-channel in the first operating mode; receiving, by the memory module through the memory interface, a command to enter a second operating mode; and communicating, by the memory module through the memory interface, third data stored in the first plurality of banks and fourth data stored in the second plurality of banks to the host device through the first sub-channel in the second operating mode.

In an additional aspect of the disclosure, an apparatus includes a memory controller with a first physical interface for communicating through a first sub-channel with a memory module and a second physical interface for communicating through a second sub-channel with the memory module, wherein the memory controller is configured to perform operations including communicating with the memory module through the first sub-channel and the second sub-channel in a first operating mode; providing a command for the memory module to enter a second operating mode; and communicating with the memory module only through the first sub-channel in the second operating mode. In some embodiments, the apparatus is a host device and the memory controller may be included in the host device along with one or more processing components.

In an additional aspect of the disclosure, a method includes communicating, by a host device, with a first plurality of banks of a memory module through a first sub-channel and with a second plurality of banks of the memory module through a second sub-channel in a first operating mode; providing, from the host device to the memory module, a command for the memory module to enter a second operating mode; and/or communicating, by the host device, with the first plurality of banks and the second plurality of banks only through the first sub-channel in the second operating mode.

In an additional aspect of the disclosure, an apparatus, such as a wireless device, includes at least one processor and a memory coupled to the at least one processor. The at least one processor is configured to communicate with the memory system through a memory controller coupled to a channel that couples the processor to the memory system. The at least one processor may include a CPU, a plurality of CPUs organized as a CPU cluster, a GPU, a NPU, or a modem.

Memory systems in the present disclosure may be embedded within a processor on a semiconductor die or be part of a different semiconductor die and coupled to the at least one processor. The memory systems may be of various kinds. For example, the memory may be static random access memory (SRAM), dynamic random access memory (DRAM), magnetic random access memory (MRAM), NAND flash, or NOR flash, etc.

Methods and apparatuses are presented in the present disclosure by way of non-limiting examples of Low-Power Double Data Rate (LPDDR) Synchronous Dynamic Random Access Memory (SDRAM). For example, the LPDDR memory may operate in accordance with LPDDR specification promulgated by Joint Electronic Device Engineering Council (JEDEC). One such LPDDR specification is LPDDR5, published as JESD209-5, Standard for Low Power Double Data Rate 5 (LPDDR5). Another such LPDDR specification is LPDDR6.

Other aspects, features, and implementations will become apparent to those of ordinary skill in the art, upon reviewing the following description of specific, exemplary aspects in conjunction with the accompanying figures. While features may be discussed relative to certain aspects and figures below, various aspects may include one or more of the advantageous features discussed herein. In other words, while one or more aspects may be discussed as having certain advantageous features, one or more of such features may also be used in accordance with the various aspects. In similar fashion, while exemplary aspects may be discussed below as device, system, or method aspects, the exemplary aspects may be implemented in various devices, systems, and methods.

The method may be embedded in a computer-readable medium as computer program code comprising instructions that cause at least one processor to perform the steps of the method. In some embodiments, the at least one processor may be part of a mobile device including a first network adaptor configured to transmit data, such as images or videos in a recording or as streaming data, over a first network connection of a plurality of network connections. The at least one processor may be coupled to the first network adaptor and a memory for storing data to support the processing and communications operations performed by the at least one processor. The network adaptor may support communication over a wireless communications network such as a 5G NR communication network. The at least one processor may cause the transmission of data stored in memory over the wireless communication network.

The foregoing has outlined, rather broadly, the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.).

While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described aspects. For example, transmission and reception of wireless signals necessarily includes a number of components for analog and digital purposes (e.g., hardware components including antenna, radio frequency (RF)-chains, power amplifiers, modulators, buffer, processor(s), interleaver, adders/summers, etc.). It is intended that innovations described herein may be practiced in a wide variety of devices, chip-level components, systems, distributed arrangements, end-user devices, etc. of varying sizes, shapes, and constitution.

### BRIEF DESCRIPTION OF THE DRAWINGS

A further understanding of the nature and advantages of the present disclosure may be realized by reference to the following drawings. In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

FIG. 1 shows a block diagram of an example computing system incorporating a host, memory system, and channels coupling the host and the memory system according to some embodiments of the disclosure.

FIG. 2 shows a block diagram of an example computing system incorporating a host, memory system, and sub-channels coupling the host to memory die according to some embodiments of the disclosure.

FIG. 3A is an example flow chart illustrating a method for a memory device to communicate with a host device through a reconfigurable number of sub-channels according to some embodiments of the disclosure.

FIG. 3B is an example flow chart illustrating a method for a host device to communicate with a memory device through a reconfigurable number of sub-channels according to some embodiments of the disclosure.

FIG. 4 illustrates a block diagram for operating a memory device in a second operating mode with disabled sub-channels according to some embodiments of the disclosure.

FIG. 5 illustrates a block diagram for a dual-rank memory die configuration with multiple operating modes according to some embodiments of the disclosure.

FIG. 6 illustrates a block diagram for a memory die configuration fixed in efficiency mode according to some embodiments of the disclosure.

Like reference numbers and designations in the various drawings indicate like elements.

### DETAILED DESCRIPTION

The detailed description set forth below, in connection with the appended drawings, is intended as a description of various configurations and is not intended to limit the scope of the disclosure. Rather, the detailed description includes specific details for the purpose of providing a thorough understanding of the inventive subject matter. It will be apparent to those skilled in the art that these specific details are not required in every case and that, in some instances, well-known structures and components are shown in block diagram form for clarity of presentation.

The present disclosure provides systems, apparatus, methods, and computer-readable media that support memory operations, including techniques for reducing power consumption in memory operations by dynamically adjusting a bandwidth available for accessing the memory without losing access to any portions of the memory. A memory die may include banks of memory cells organized for access through sub-channels. The memory die may include two or more groups or pluralities of banks of memory cells organized for access through respective (physical) sub-channels. In other words, each of the two or more pluralities of banks may be provided with its own, dedicated (physical) sub-channel. A physical sub-channel may be defined as circuitry providing access to a plurality of banks. Such circuitry may include a (dedicated) memory interface, such as a PHY interface of a memory controller, for accessing the plurality of banks, as described in more detail below with reference to the Figures. For example, a memory die may include a first plurality of memory banks and a second plurality of memory banks, with the first plurality of memory banks accessible through a first sub-channel and the second plurality of memory banks accessible through a second sub-channel. In an efficiency mode, the second sub-channel may be disabled and communications with the second plurality of memory banks redirected through the first sub-channel.

Particular implementations of the subject matter described in this disclosure may be implemented to realize one or more of the following potential advantages or benefits. In some aspects, the present disclosure provides improved power efficiency. For example, the bandwidth between the host device and the memory device may be dynamically controlled to match power consumption to current demands for data in the host device. The dynamic bandwidth control may be provided while still maintaining full access to the contents of both the first and second pluralities of memory banks (despite disabling the second (physical) sub-channel).

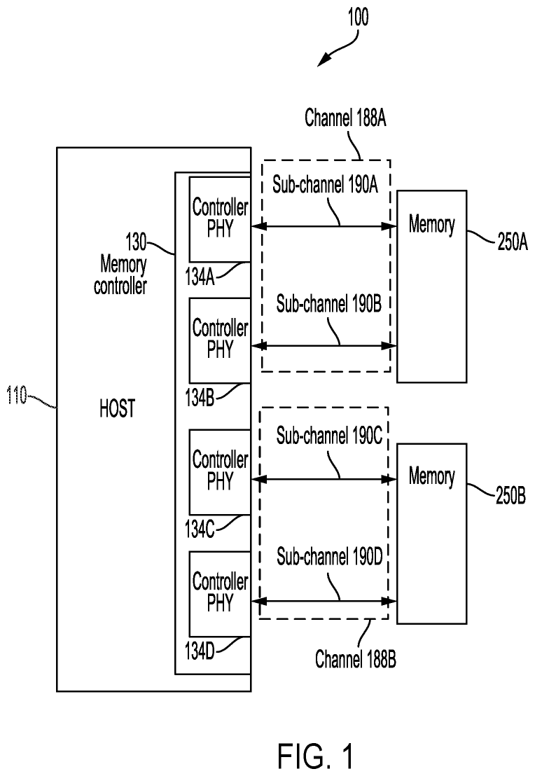

An example memory device that may incorporate aspects of this disclosure, including sub-channels configurable for efficiency mode, is shown in FIG. 1. FIG. 1 illustrates an apparatus 100 incorporating a host 110, memories 250, and channels 188 coupling the host 110 and the memories 250. The apparatus 100 may be, for example, a device among computing systems (e.g., servers, datacenters, desktop computers), mobile computing device (e.g., laptops, cell phones, vehicles, etc.), Internet of Things (IoT) devices, virtual reality (VR) systems, augmented reality (AR) systems, automobile systems (e.g., driver assistance systems, autonomous driving systems), image capture devices (e.g., stand-alone digital cameras or digital video camcorders, camera-equipped wireless communication device handsets, such as mobile telephones, cellular or satellite radio telephones, personal digital assistants (PDAs), panels or tablets, gaming devices, computing devices such as webcams, video surveillance cameras, or other devices with digital imaging or video capabilities), and/or multimedia systems (e.g., televisions, disc players, streaming devices,).

The host 110 may include at least one processor, the at least one processor include one or more cores such as a central processing unit (CPU), a graphic processing unit (GPU), a digital signal processor (DSP), a multimedia engine, and/or a neural processing unit (NPU). The host 110 may be configured to couple to and to communicate with the memories 250A-B via channels 188A-B to perform computing functions, such as one or more of data processing, data communication, graphic display, camera, AR or VR rendering, image processing, neural processing, etc. For example, the memories 250A to 250B may store instructions or data for the host 110 to perform computing functions.

The host 110 may include a memory controller 130, which may include controller physical (PHY) modules 134A-D. Each of the controller PHY modules 134A-D may be coupled to a respective one of the memory die 250A-B via respective channels 188A-188B. Each of the channels 188A-B may include multiple sub-channels, such as sub-channels 190A-B for channel 188A and sub-channels 190C-D for subchannel 188B. For case of reference, read and write are referenced from a perspective of the host 110. For example, in a read operation, the host 110 may receive data stored from one or more of the memories 250A-B via one or more of the channels 188A-B. In a write operation, the host 110 may provide data to be written into one or more of the memories 250A-B for storage via one or more of the channels 188A-B. The memory controller 130 may be configured to control various aspects of communications to and from the memories 250A-B. The controller PHY modules 134A-D may be configured to control electrical characteristics (e.g., voltage levels, phase, delays, frequencies, etc.) of signals provided or received on the channels 188A-B, respectively, to perform read or write or other memory operations.

In some examples, the memories 250A-B may be LPDDR DRAM (e.g., LPDDR5, LPDDR6). In some examples, the memories 250A-B may be different kinds of memory, such as one LPDDR5, one LPDDR6, one Flash memory, and one SRAM, respectively. The host 110, the memories 250A-B, and/or the channels 188A-B may operate according to an LPDDR (e.g., LPDDR5, LPDDR6) interface specification. In some examples, each of the channels 188A-B may have a data bitwidth of 16 bits (e.g., 16 DQs). In some examples, each of the channels 188A-B may have a data bitwidth of 32 bits (e.g., 32 DQs). In FIG. 1, two channels are shown, however the apparatus 100 may include more or less channels, such as 8 or 16 channels. Further, in some embodiments, signal lines (e.g., DQs) may be shared between sub-channels or each sub-channel may have its own dedicated bits for signal lines.

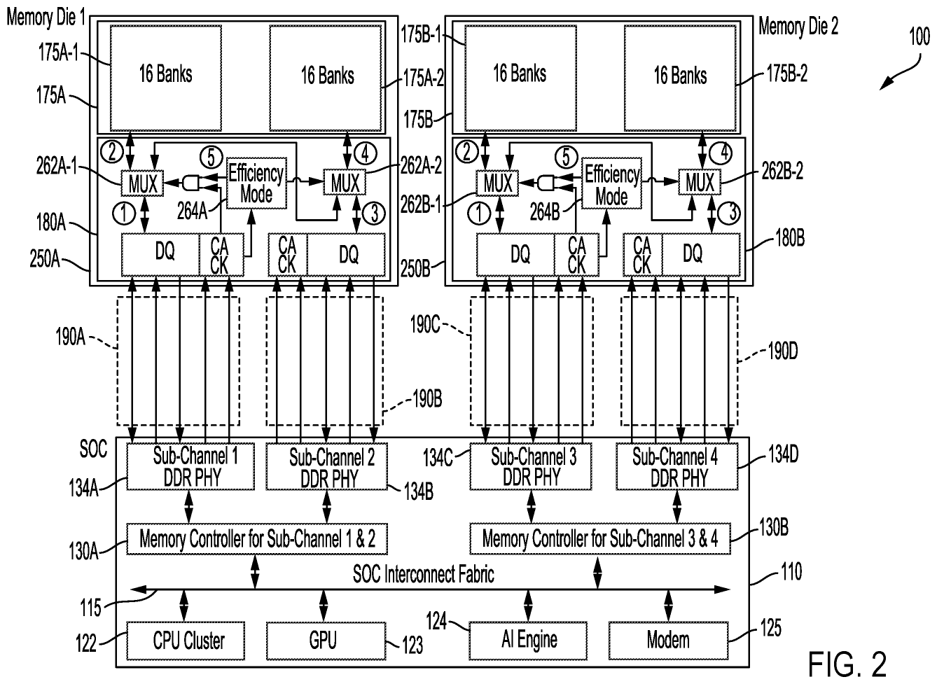

The channels 188A-B may each include multiple sub-channels providing parallel access to the memories 250A-B, respectively. The sub-channels may be controlled to dynamically adjust bandwidth to each of the memories 250A-B. Additional details of an aspect of the embodiment of the apparatus 100 for providing access to a memory system (such as one of memories 250A-B including logic and control circuit) are described with reference to FIG. 2. For example, the channels 188A-B may include individually controllable sub-channels 190A-D. Multiple sub-channels may be used to provide high-performance, high-bandwidth communication to a memory module. Some of the sub-channels may be disabled to reduce power consumption with a corresponding decrease in bandwidth. When sub-channels are disabled, the host 110 may retain access to the full range of address in the memory module, although the bandwidth for transferring data is reduced by the number of sub-channels that are disabled.

FIG. 2 illustrates a configuration of the host 110, memory die 250A-250B, and sub-channels 190A-190D. The sub-channels 190A-190D between host 110 and the memory die 250A-B may include a plurality of connections, some of which carry data (e.g., user data or application data) and some of which carry non-data (e.g., control information, such as addresses and/or other signaling information). For example, non-data connections in sub-channel 190A may include a data clock (e.g., WCK) used in communicating data with the respective memory die 250A and a read data strobe (e.g., RDQS) used in receiving data from the respective memory die 250A. The sub-channel 190A may further include a data mask (e.g., DM, sometimes referred to as data mask inversion DMI) used to mask a certain part of data in a write operation. The sub-channel 190A may further include command and address (e.g., CA [0:n]) and an associated Command Clock (CK) to provide commands (e.g., read or write commands) to the memory die 250A. Each of the sub-channels 190B-190D may be configured similar to that of sub-channel 190A.

The host 110 may include at least one processor, which may include a CPU cluster 122 (including one or more cores having execution logic and/or caches), a graphics processing unit (GPU) 123, a neural processing unit (NPU) 124 (e.g., an AI engine), and/or a modem 125. The host 110 may further include memory controllers 130A-130B, each of the controllers 130A-130B coupled to two or more PHY interfaces (e.g., PHY interfaces 134A-B for memory controller 130A) coupled to the memory die 250A-B through a sub-channel. In some aspects, the PHY interfaces 134 may be DDR PHY interfaces. In the embodiment shown in FIG. 2, each of the memory controllers 130A-B has two sub-channels in the channel, such that memory controller 130A is coupled to PHY interfaces 134A and 134B and memory controller 130B is coupled to PHY interfaces 134C and 134D. However, the memory controllers 130A and 130B in other embodiments may be configured with N and M sub-channels, respectively, in which N may be equal to M or N may be different from M, where N and M are integer numbers larger than one. In some aspects, N and M may be powers of two.

The memory controllers 130A-130B may couple to the at least one processor via a bus 115 for communicating information while performing various computing functions. A bus 115 may encompass multiple physical connections as well as intervening stages such as buffers, latches, registers, etc. The memory controllers 130A-130B may be part of a memory interconnect between the CPU cluster 122, GPU 123, NPU 124, and/or modem 125 and the memory die 250A and 250B.

The memory die 250A-250B may include memory interfaces 180A-180B, respectively, each configured to provide or to receive signals on connections of the sub-channels 190A-190D. Memory interfaces 180A-180B may be configured to capture (e.g., to sample) data, commands, and addresses from the host 110 via the sub-channels 190A-190D and to output data to the host 110 via the sub-channels 190A-190D. Memory interfaces 180A-180B may include buffers (or other short-term memory) and/or logic circuitry for decoding and executing commands received from the memory controllers 130A-130B of the host device 110.

Memory interfaces 180 may include data processing circuitry DQ corresponding to each sub-channel 190 for decoding and/or encoding data on bus lines corresponding to Data Bus [0:k-1], Write Data Clock (WCK), and Read Data Clock (RDQ). Memory interfaces 180 may also include command processing circuitry CA/CK corresponding to each sub-channel 190 for decoding and/or encoding data on bus lines corresponding to CA Bus [0:m-1] and Command Clock (CK). The integers m and k correspond to respective bitwidths of the command bus and data bus, respectively. In a two sub-channel configuration as shown in FIG. 2, the DQ blocks in a die 250 may provide data to multiplexers (e.g., multiplexer 262A-1 and 262A-2) and the CA/CK blocks in a die 250 may provide data to multiplexers (e.g., 262A-1 and 262A-2) as a control signal.

For example, memory interface 180A of memory die 250A may receive signals through sub-channels 190A and 190B from memory controller 130A. Memory interface 180B of memory die 250B may receive signals through sub-channels 190C and 190D from memory controller 130B. The sub-channels 190A and 190B may include duplicative sets of signals such that the memory interface 180A may communicate with memory die 250A if either of the sub-channels 190A or 190B is disabled. When both sub-channels 190A and 190B are enabled, the memory controller 130 may communicate with the memory interface 180A through sub-channel 190A and sub-channel 190B. For example, the memory controller 130A may issue separate commands through the sub-channel 190A and the sub-channel 190B to access memory cells in parallel to achieve higher bandwidth than when operating on one sub-channel.

The memory die 250A-250B may include memory cells 175 (e.g., DRAM memory cells, MRAM memory cells, SRAM memory cells, Flash memory cells) that store values corresponding to user or application data. The memory cells 175A-175B of die 250A-B. respectively, may each be organized into a plurality of banks, and the banks may be grouped for access through the sub-channels 190A-190D. For example, the memory die 250A may include a first plurality of banks 175A-1 accessible through the sub-channel 190A and a second plurality of banks 175A-2 accessible through the sub-channel 190B. As another example, the memory die 250B may include a first plurality of banks 175B-1 accessible through the sub-channel 190C and a second plurality of banks 175B-2 accessible through the sub-channel 190D. Each bank may be further divided and organized as a plurality of pages.

Although the memory cells 175 may be organized as pluralities of banks associated with corresponding sub-channels, the different pluralities of banks may be accessed through another of the sub-channels. Some banks may be accessible through other sub-channels when the memory die 250 are operating in an efficiency mode with some sub-channels disabled as described in further detail below. For example, if sub-channel 190B is disabled, the second plurality of banks 175A-2 may be accessed through the sub-channel 190A otherwise associated with the first plurality of banks 175A-1.

Access to some banks through alternative sub-channels may be provided through logic circuitry, such as multiplexers 262 and AND gates, which may be controlled, e.g., through mode registers 264A-264B, to change the data flow in the memory die 250. Each sub-channel 190 for a specific memory controller 130 may correspond to a respective multiplexer 262 of the memory interface 180 corresponding to the specific memory controller. Thus, each of the plurality of banks 175A-B may be coupled to a respective multiplexer 262. The multiplexers are coupled to each other to permit accessing all of the pluralities of banks 175A-B which correspond to the sub-channels 190 for the specific memory controller.

The multiplexers may be controlled to provide access to a particular plurality of banks (e.g., to route data and/or signals from a specific sub-channel to the particular plurality of banks) via a control element of the memory interface 180, such as mode registers 264. For example, communications with the second plurality of banks 175A-2 through the sub-channel 190A and the sub-channel 190B may be provided by first multiplexer 262A-1 and second multiplexer 262A-2. The first multiplexer 262A-1 receives signals from the sub-channel 190A and applies them to the first plurality of banks 175A-1 or the second multiplexer 262A-2. To this end, the first multiplexer 262A-1 also couples to the second multiplexer 262A-2. Whether the first multiplexer 262A-1 passes the received signals to the first plurality of banks 175A-1 or the second multiplexer 262A-2 may be controlled by circuitry, such as the depicted command and address (CA) bus, of the memory interface 180A. In the illustrative example of FIG. 2, a control signal (e.g., based on control information such as the SC operand described further below) from the CA bus is passed through an AND gate together with a signal from the mode register 264A to a control input of the multiplexer 262A-1. Different implementations, e.g., using alternative logic circuitry, are possible, e.g., depending on the content of the mode register.

When a mode register 264A is set for a first operating mode (such as a performance mode), the first multiplexer 262A-1 does not pass signals from sub-channel 190A to the second multiplexer 262A-2. When the mode register 264A is set for a second operating mode (e.g., an efficiency mode in which sub-channel 190B is disabled), the first multiplexer 262A-1 passes signals from sub-channel 190A to the second plurality of banks 175A-2 through the second multiplexer 262A-2. The second multiplexer 262A-2 is similarly configured by the mode register 264A to configure whether the data for the second plurality of banks 175A-2 is received through one or the other of the two DQ blocks. When the mode register 264A is set for the first operating mode, the second multiplexer 262A-2 passes signals from sub-channel 190B to the second plurality of banks 175A-2. In this first operating mode, sub-channels 190A and 190B may thus be used independently and in parallel to access the first plurality of banks 175A-1 and the second plurality of banks 175A-2, respectively. When the mode register 264A is set for the second operating mode, the second multiplexer 262A-2 passes signals from the first multiplexer 262A-1 to the second plurality of banks 175A-2.

The mode register 264A-264B may control the multiplexers only when certain commands are provided to the memory die 250. For example, some commands (Bank Active, Write, Read, Precharge, Refresh) from a host to a memory device may include an indication of a sub-channel bank (e.g., indicating the plurality of banks 175A-1 or 175A-2). When these commands are received, multiplexer 262A-1 and 262-A2 are controlled by the mode register 264A and an output of a command decoder processing such a command that indicates a sub-channel bank. In one embodiment using the die 250A as an example, the output of the command decoder CA/CK block may be combined, such as through an AND gate, with an output of the mode register 264A to determine a control input to the multiplexer 262A-1.

Application or user data may be processed by the at least one processor of the host device 110, resulting in the at least one processor instructing the memory controllers 130A-130B to store and/or retrieve data from the memory die 250A-250B. For example, data may be generated during the execution of an application, such as a spreadsheet program that computes values based on other data. As another example, data may be generated during the execution of an application by receiving user input to, for example, a spreadsheet program. As a further example, data may be generated during the execution of a gaming application, which generates information regarding a representation of a scene rendered by a three-dimensional (3-D) application.

The sub-channels 190A-190D carry signaling between the host 110 and the memory die 250A-250B and may be implemented in accordance with the JEDEC DRAM specification (e.g., LPDDR5, LPDDR6). In some embodiments, the sub-channels 190A-190D each include signal connections of data (DQ [0:k-1] for a buswidth of k with k being a power of two), a read data strobe (RDQS), a data mask (DM), a data clock (WCK), command and address (CA [0:n] for an address length of n), and command and address clock (CK). The host 110 may use the read data strobe RDQS to strobe (e.g., to clock) data in a read operation to receive the data on the data pins (DQs). The memory die 250A-250B may use the data mask DM to mask certain parts of the data from being written in a write operation. The memory die 250A-250B may use the data clock WCK to sample data on the DQs for a write operation. The memory die 250A-250B may use the command and address clock CK to clock (e.g., to receive) the CAs. A signal connection for each of the signals may include a pin at the host 110, a pin at a memory die, and a conductive trace or traces electrically connecting the pins. The conductive trace or traces may be part of a single integrated circuit (IC) containing the at least one processor and the memory die 250A-250B as a System on Chip (SoC) using a package on package (PoP) construction.

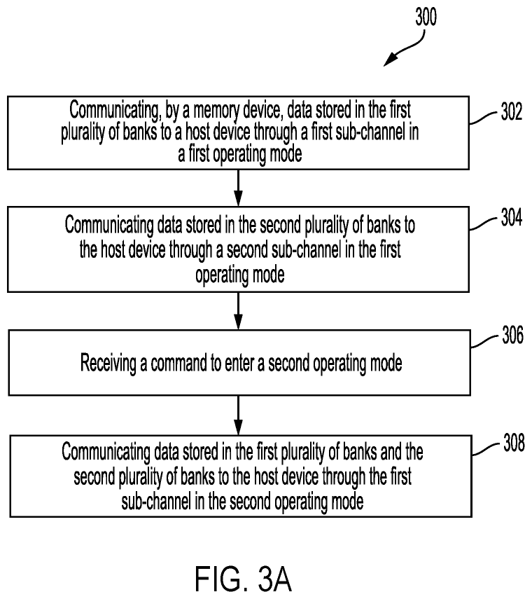

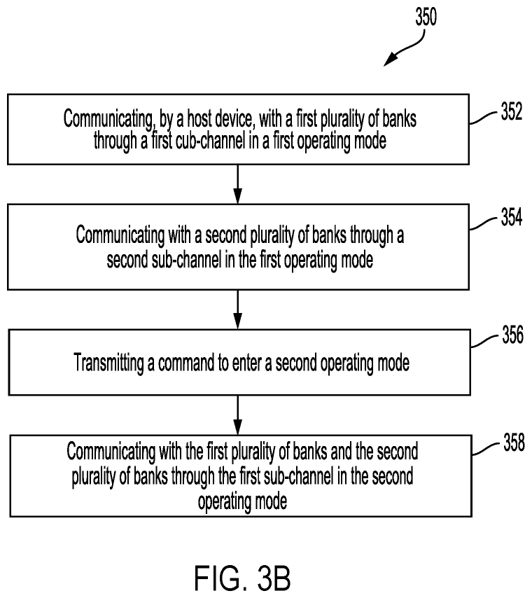

An operation for communicating data by a memory device, such as one of the memory die 250, is shown in FIG. 3A. FIG. 3A is an example flow chart illustrating a method for a memory device to communicate with a host device through a reconfigurable number of sub-channels according to some embodiments of the disclosure. A method 300 includes, at block 302, communicating data stored in a first plurality of banks to a host device through a first sub-channel (of a channel) in a first operating mode. For example, with reference to FIG. 2, a memory device (memory die 250A) may communicate data to or from the first plurality of banks 175A-1 through the first sub-channel 190A. The communication may include storing data into or retrieving data from the first plurality of banks 175A-1.

At block 304, the method 300 includes communicating data stored in a second plurality of banks to the host device through a second sub-channel (of the same channel) in the first operating mode. For example, with reference to FIG. 2, the memory device (memory die 250A) may communicate data to or from the second plurality of banks 175A-2 through the second sub-channel 190B. The communication may include storing data into or retrieving data from the second plurality of banks 175A-2 (of the same memory die 250A).

At block 306, the method 300 includes receiving a command to enter a second operating mode. The command may be received from the host device or determined internally by the memory device. The command may be, for example, a Mode Register Write (MRW) operation that programs a value into an Efficiency Mode register corresponding to efficiency mode. With memory die 250A in the efficiency mode, the sub-channel 190B may be disabled. Disabling the sub-channel 190B may include disconnecting one or more clocks, such as the Command Clock (CK) and/or the Write Data Clock (WCK), configuring signal lines into a Hi-Z state, and/or disabling circuit in the host device 110 associated with the sub-channel 190B (e.g., by disconnecting a voltage rail and/or clock signal from the PHY interface corresponding to the sub-channel 190B). In the second operating mode, bandwidth of the first sub-channel is shared by the first plurality of banks and the second plurality of banks.

In the second operating mode, the first or second plurality of banks can be selectable by an “SC” operand associated with a memory operation. The “SC” operand indicates one of the plurality of banks in a Bank Active command sent prior to a Read command as part of a read operation. An “SC” operand indicating which of the banks a command applies to may also be attached to other commands transmitted to the memory die, including Bank Pre-charge (PRE), Refresh (REF), Write (WR-S, WR-L) and Read (RD-S, RD-L) commands. For example, if the SC operand is the value “1b” in a Refresh command, the refresh operation executes for the second plurality of banks. If the SC operand is the value “0b” in a Refresh command, the refresh operation executes for the first plurality of banks. Commands transmitted between the host device and the memory device that may be applied to all pluralities of banks regardless of operating mode may include NOP, Power Down Entry and Exit, Self-Refresh Entry and Exit, Mode Register Write, Mode Register Read, and/or training-related commands. Commands transmitted between the host device and the memory device that may have an operand specifying one of the pluralities of banks may include Bank Activate, Pre-charge, Refresh, Write, and/or Read. In the first operating mode, the “SC” operand may be ignored, e.g., by passing it through an AND gate together with a value “0b” from the mode register 262A.

In some embodiments, a memory housekeeping policy, such as refresh or row hammer mitigation, is maintained for the different pluralities of banks independently regardless of the operating mode. For example, the first memory controller 130A may include two refresh management units. The first refresh management unit controls the refresh of the first plurality of banks 175A-1 and the second refresh management unit controls the refresh of the second plurality of banks 175A-2. The refresh requirement of a memory device may be independent from the memory operating mode (e.g., efficiency or normal/performance mode) and host bandwidth requirements. Therefore, the first and the second refresh management units continue applying to the first plurality of banks 175A-1 and the second plurality of banks 175A-2, respectively, regardless of the operating mode. In the efficiency operating mode, the refresh command with an “SC” operand is delivered throughout the sub-channel 190A.

At block 308, while in the second operating mode, the memory device communicates data stored in both the first and second plurality of banks through the first sub-channel. For example, with reference to FIG. 2, the host device 110 communicates with both the first plurality of banks 175A-1 and the second plurality of banks 175A-2 through the sub-channel 190A. Circuitry in the memory interface 180A may be configured in the efficiency mode to couple the second plurality of banks 175A-2 to the sub-channel 190A. Portions of the memory interface 180A comprising logic circuitry corresponding to the sub-channel 190B may be disabled in the efficiency mode.

Although certain example operations described with reference to FIG. 3A describe the transmission of data from the memory device to the host device, referred to as a “read” operation, the steps of “communicating” may also or alternatively include the reception of data at the memory device from the host device, referred to as a “write” operation. In a read operation data is transmitted from one or more banks of the memory device to the host device in response to a request from the host device based on an address associated with the read command. The host device may operate on the data in an application executed by the user. In a write operation data is transmitted from the host device to the memory device as part of a request to store data in one or more banks of the memory device based on an address associated with the write command. The data may be retrieved at a later time as part of a read operation for the data to be recalled and operated on by an application executed by the user.

An operation for communicating by the host device with the memory device may include corresponding steps on the host device for the steps described in FIG. 3A for the memory device. For example, the host device may communicate with the memory device by receiving data on the data bus of a sub-channel when a memory device communicates with the host device by transmitting data on a data bus of a sub-channel. As another example, the host device may transmit a command to the memory device when the memory device receives a command.

An operation for communicating data by the host device 110, such as an SoC, is shown in FIG. 3B. FIG. 3B is an example flow chart illustrating a method for a host device to communicate with a memory device through a reconfigurable number of sub-channels according to some embodiments of the disclosure. A method 350 includes, at block 352, communicating, with a memory device, data in a first plurality of banks through a first sub-channel (of a channel) in a first operating mode. For example, with reference to FIG. 2, the host device 110 may communicate data to or from the first plurality of banks 175A-1 of the memory device (memory die 250A) through the first sub-channel 190A. The communication may include storing data into or retrieving data from the first plurality of banks 175A-1.

At block 354, the method 350 includes communicating with a second plurality of banks through a second sub-channel (of the same channel) in the first operating mode. For example, with reference to FIG. 2, the host device may communicate data to or from the second plurality of banks 175A-2 of the memory device (memory die 250A) through the second sub-channel 190B. The communication may include storing data into or retrieving data from the second plurality of banks 175A-2 (of the same memory die 250A).

At block 356, the method 350 includes transmitting a command to the memory device to enter a second operating mode. The command may be transmitted from the host device to the memory device. Switching to the second operating mode may be determined from one or more rules based on conditions monitored by the host device 110, such as a reduced demand on bandwidth (e.g., for performing operations, such as executing one or more specific applications, by the at least one processor). For example, providing a command for the memory module to enter the second operating mode may be performed based on a rule comprising one or more criteria based on a mode of operation of the at least one processor

In some embodiments, the second operating mode, which may be referred to as efficiency mode, may be triggered when a component coupled to the memory device enters a low-power mode. The low-power mode may include switching a component to a lower performance level (e.g., a lower voltage and/or clock). For example, the second operating mode may be activated when some of the cores in the CPU cluster 122 enter a sleep mode because the bandwidth demand from the memory die 250A may be decreased with fewer devices communicating data. As another example, the second operating mode may be activated when a clock frequency of the CPU cluster 122 is below a threshold because the bandwidth demand by the CPU cluster 122 decreases with clock frequency. As a further example, the second operating mode may be activated based on workloads of one or a combination of the CPU cluster 122, the GPU 123, the NPU 124, and/or the modem 125. As another example, the second operating mode may be activated based on a wireless channel configuration of the modem 125. When the modem 125 is configured in a low bandwidth mode, such as single carrier operation (instead of carrier aggregation operation), the second operating mode may be activated based on a reduced bandwidth demand to store data communicated over the wireless communication network.

The command of block 356 may be, for example, a Mode Register Write (MRW) operation that programs a value into an Efficiency Mode register corresponding to efficiency mode. With memory die 250A configured/programed in the efficiency mode, the sub-channel 190B may be disabled. Disabling the sub-channel 190B may include disconnecting one or more clocks, such as the Command Clock (CK) and/or the Write Data Clock (WCK), configuring signal lines into a Hi-Z state, and/or disabling circuitry in the host device 110 associated with the sub-channel 190B (e.g., by disconnecting a voltage rail and/or clock signal from the PHY interface corresponding to the sub-channel 190B).

Portions of the host device 110 corresponding to the sub-channel 190B may be disabled in the efficiency mode. For example, the PHY interface 134B may be disabled by disconnecting a supply voltage and/or clock frequency when the memory die 250A is configured in efficiency mode.

At block 358, the method 350 includes communicating with the first plurality of banks and the second plurality of banks through the first sub-channel while in the second operating mode. While in the second operating mode, the host device communicates data stored in both the first and second plurality of banks of the memory device through the first sub-channel. For example, with reference to FIG. 2, the host device 110 communicates with both the first plurality of banks 175A-1 and the second plurality of banks 175A-2 through the sub-channel 190A only.

When the memory device enters the second operating mode, the memory device provides access to all banks of memory (of the memory die(s)) through fewer than all sub-channels. In the example of FIG. 2, in which each memory die is divided into two pluralities of banks with two corresponding sub-channels to each memory die, the second operating mode may have one of the two sub-channels may be disabled. Although some sub-channels are disabled, the host device may retain access to all of the banks through a circuit configuration that reconfigures to couple the banks corresponding to the disabled sub-channel to the active sub-channel (e.g., using the multiplexers and mode register shown in FIG. 2). Although two pluralities of banks (e.g., sets of banks) are illustrated in a memory die in various example embodiments, a memory die may be organized into additional pluralities of banks and additional sub-channels. Further, in some embodiments, there may be more pluralities of banks than sub-channels such that there is, generally, a ratio of N pluralities of banks to M sub-channels. In such embodiments, circuitry may be configured to couple additional pluralities of banks through the active/enabled sub-channels.

Returning to the example embodiment of FIG. 2 having two pluralities of banks with two corresponding sub-channels, one of the sub-channels may be disabled in the second operating mode.

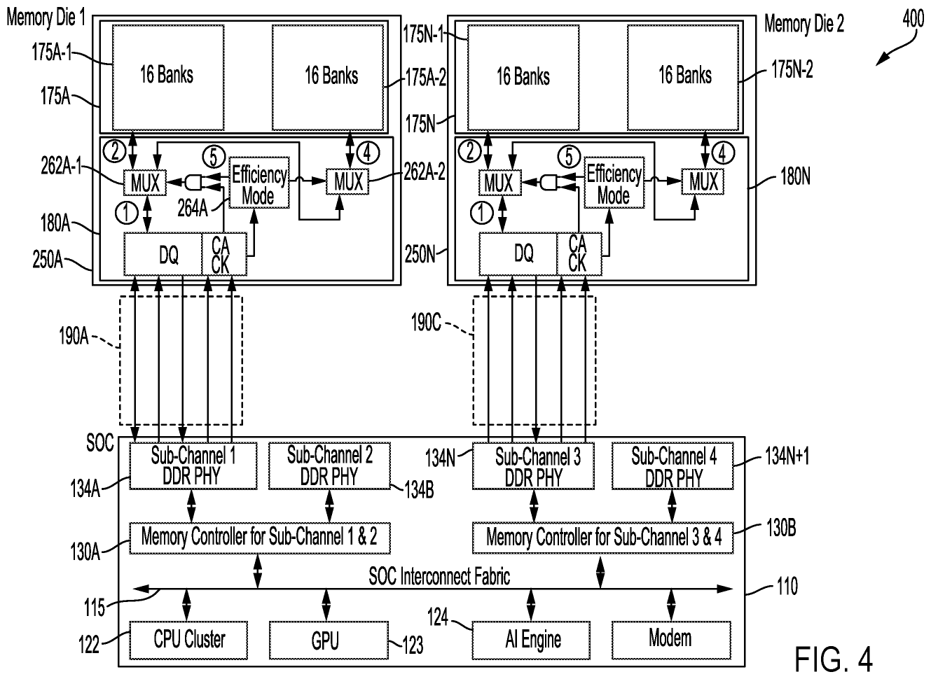

FIG. 4 illustrates a block diagram for operating a memory device in a second operating mode with disabled sub-channels according to some embodiments of the disclosure. In configuration 400, sub-channels 190B and 190D are disabled, which may reduce power consumption compared to operation in the configuration of FIG. 2.

The second operating mode may be activated by configuring an efficiency mode block 264A with a setting indicating the second operating mode. For example, the efficiency mode block 264A may be a register in which a first value (e.g., ‘0b’) indicates the first operating mode and a second value (e.g., ‘1b’) indicates the second operating mode. The register value in efficiency mode block 264A may be coupled to the inputs of multiplexers 262A-1 and 262A-2 to configure the multiplexers. In the second operating mode, the first multiplexer 262A-1 may be configured to couple the first sub-channel 190A to the first plurality of banks 175A-1 and also the second plurality of banks 175A-2, e.g., depending on a value of an SC operand as described above. To facilitate communications with the second plurality of banks 175A-2 through the first sub-channel 190A, the second multiplexer 262A-2 is configured by the register value to couple the second plurality of banks 175A-2 to the first multiplexer 262A-1 rather than to the second sub-channel 190B.

Although the example embodiments of FIG. 2 and FIG. 4 illustrate a two channel configuration with two memory die 250A and 250B, other embodiments may include other channel configurations, such as four channels, eight channels, sixteen channels, or more channels and a corresponding number N of memory die. The multiplexers of other memory die, e.g., die 250B, may be switched jointly with the memory die 250A such that some or all of N (N greater than one) memory die switch to efficiency mode together. The multiplexers of other memory die, e.g., 250B, may be switched separately from the memory die 250A such that some or all of the N memory die may be switched independently to efficiency mode. In efficiency mode, if the host has a need for high bandwidth performance, all or some memory die may switch to performance mode from the efficiency mode. Further, although the example embodiments of FIG. 2 and FIG. 4 illustrate a single rank configuration, other embodiments may include other rank configurations, such as two ranks, four ranks, eight ranks, or more ranks.

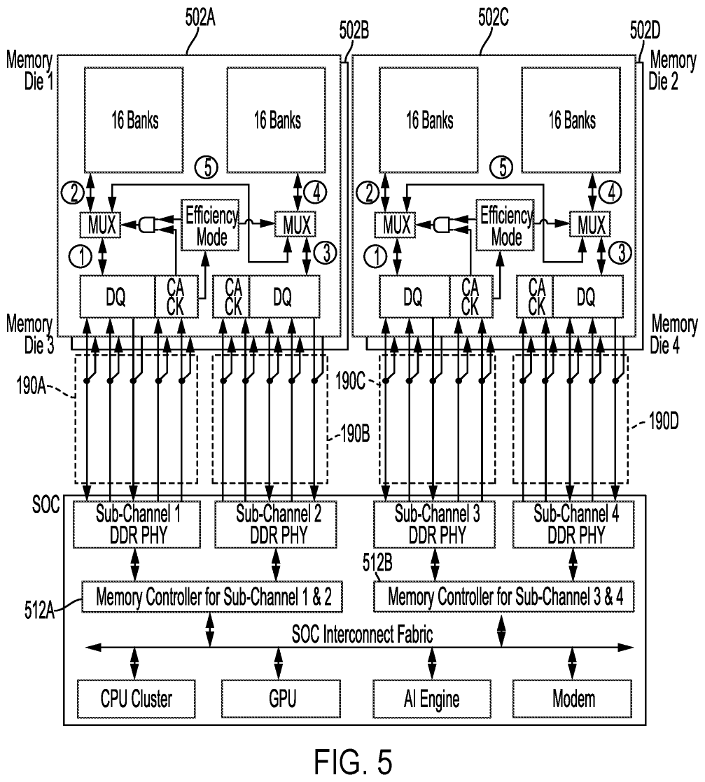

FIG. 5 illustrates a block diagram for a dual-rank memory die configuration with multiple operating modes according to some embodiments of the disclosure. A two-rank configuration as in FIG. 5 includes two memory die coupled to the same sub-channels. For example, a first memory die 502A and a second memory die 502B are both coupled to sub-channels 190A and 190B. A first plurality of banks of the first memory die 502A and a first plurality of banks of the second memory die 502B are both coupled to sub-channel 190A. A second plurality of banks of the first memory die 502A and a second plurality of banks of the second memory die 502B are both coupled to sub-channel 190B. Likewise, a first plurality of banks of the third memory die 502C and a first plurality of banks of the fourth memory die 502D are both coupled to sub-channel 190C. A second plurality of banks of the third memory die 502C and a second plurality of banks of the fourth memory die 502D are both coupled to sub-channel 190D. In general, for an N-rank configuration, N memory die are coupled to the same sub-channels wherein corresponding pluralities of banks of the N memory die are coupled to the same sub-channel.

Disabling sub-channel 190B, such as by activating an efficiency mode of a first memory controller 512A, configures the memory die 502A and 502B to communicate from all banks through the first sub-channel 190A. Likewise, disabling sub-channel 190D, such as by activating an efficiency mode of a second memory controller 512B, configures the memory die 502C and 502D to communicate from all banks through the first sub-channel 190C.

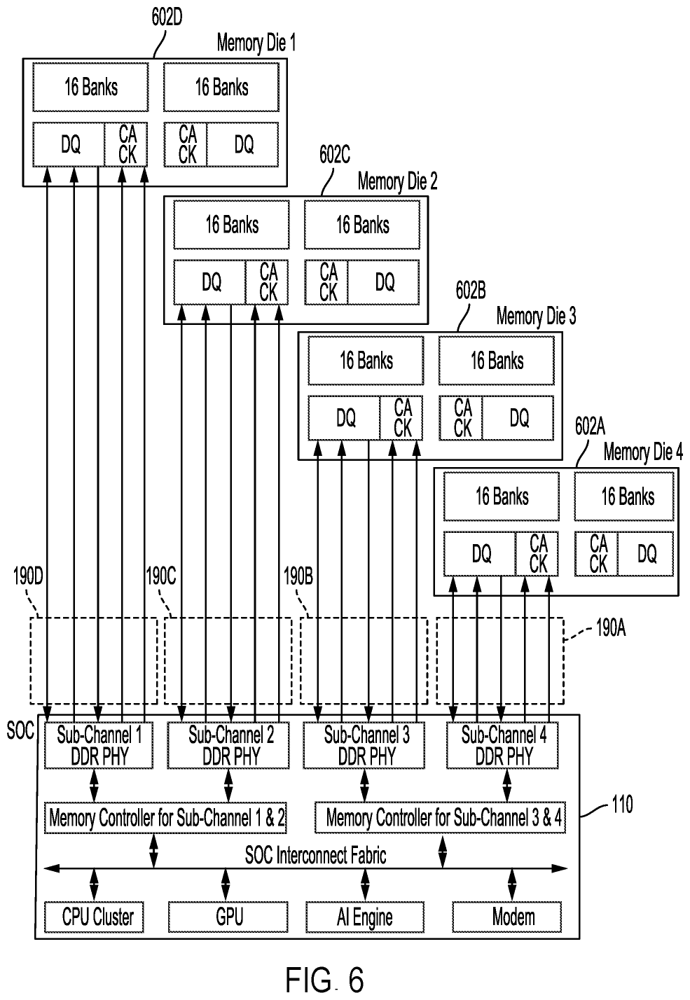

In some embodiments, a memory die supporting multiple sub-channels may be coupled to a host device through a single sub-channel. In such a configuration, the efficiency mode for the memory die may be always active, such as through the configuring of a value permanently into a read only memory (ROM) or by activating a fuse to permanently couple multiplexers for communication through a single sub-channel. In some embodiments, the host device configures the efficiency mode register through a configuration operation at the startup of the host device. The configuration of embodiments such as FIG. 6 may provide increased memory capacity without expanding the number of memory controllers in the host device.

FIG. 6 illustrates a block diagram for a memory die configuration fixed in efficiency mode according to some embodiments of the disclosure. Memory die 602A-602D may be coupled to sub-channels 190A-190D, respectively. Each memory die 602A-602D is configured to operate in efficiency mode such that all banks of each of the memory die are accessible through a single sub-channel. For example, the memory die 602A-602D may be configured with multiplexers to bypass circuitry associated with a sub-channel interface that is not coupled to the host device. The illustration of FIG. 6 for the memory die 602A-D omit some details of the operation and selection of the plurality of banks in each memory die 602A-D. However, the memory die 602A-D should be understood, in some embodiments, to include the hardware illustrated in further detail in memory die 250A-B as in FIG. 2, or other hardware elements described in embodiments with respect to FIG. 1, FIG. 2, FIG. 3, FIG. 4, FIG. 5, or elsewhere in this disclosure.

A wireless communications device may include a memory system as illustrated in at least FIG. 1, FIG. 2, FIG. 4, FIG. 5, and/or FIG. 6 and configured to receive and output data from the memory die in the first operating mode and the second operating mode. The memory system according to any of the aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, or avionics systems.

In one or more aspects, techniques for memory storage and retrieval may include additional aspects, such as any single aspect or any combination of aspects described below or in connection with one or more other processes or devices described elsewhere herein. In a first aspect, supporting data operations may include an apparatus configured to store and retrieve data, such as a memory device with a memory interface and one or more memory cells accessed through the memory interface. According to a first aspect, the apparatus may include a memory interface coupled to a first plurality of banks and a second plurality of banks, the memory interface configured to couple the first plurality of banks and the second plurality of banks to a host device through a first sub-channel and a second sub-channel, and the memory interface configured to perform operations comprising: communicating first data stored in the first plurality of banks to the host device through the first sub-channel in a first operating mode; communicating second data stored in the second plurality of banks to the host device through the second sub-channel in the first operating mode; receiving a command to enter a second operating mode; and communicating third data stored in the first plurality of banks and fourth data stored in the second plurality of banks to the host device through the first sub-channel in the second operating mode.

Additionally, the apparatus may perform or operate according to one or more aspects as described below. In some implementations, the apparatus is a wireless device, such as a UE, that includes the memory interface and memory cells. In some implementations, the apparatus may include at least one processor (including one or more of a CPU, GPU, AI Engine, and/or modem), and a memory coupled to the processor. The processor may be configured to perform operations described herein with respect to the apparatus. In some other implementations, the apparatus may include a non-transitory computer-readable medium having program code recorded thereon and the program code may be executable by a computer for causing the computer to perform operations described herein with reference to the apparatus. In some implementations, the apparatus may include one or more means configured to perform operations described herein. In some implementations, a method of wireless communication may include one or more operations described herein with reference to the apparatus.

In a second aspect, in combination with the first aspect, the memory interface comprises a first multiplexer configured to couple the first sub-channel to the first plurality of banks in the first operating mode; a second multiplexer configured to couple the second sub-channel to the second plurality of banks in the first operating mode, wherein the first multiplexer is further configured to couple the first sub-channel to the first plurality of banks or the second multiplexer in the second operating mode based at least in part on control information received from the first sub-channel; and wherein the second multiplexer is further configured to couple the first multiplexer to the second plurality of banks in the second operating mode.

In a third aspect, in combination with one or more of the first aspect or the second aspect, the memory interface further comprises control circuitry configured to control the first multiplexer and the second multiplexer such that the first multiplexer couples the second plurality of banks to the first sub-channel based on the mode register and the control information.

In a fourth aspect, in combination with one or more of the first aspect through the third aspect, the control circuitry comprises a mode register configured to store a first value corresponding to the first operating mode or a second value corresponding to the second operating mode.

In a fifth aspect, in combination with one or more of the first aspect through the fourth aspect, receiving the command to enter the second operating mode comprises receiving a mode register write command setting the mode register to the second value corresponding to the second operating mode.

In a sixth aspect, in combination with one or more of the first aspect through the fifth aspect, the control circuitry further comprises logic circuitry configured to receive the control information and a stored value from the mode register for controlling the first multiplexer.

In a seventh aspect, in combination with one or more of the first aspect through the sixth aspect, the first sub-channel comprises a first data bus, a first clock signal, and a first command and address bus, and the second sub-channel comprises a second data bus, a second clock signal, and a second command and address bus, wherein the control information is received from the first command and address bus.

In an eighth aspect, in combination with one or more of the first aspect through the seventh aspect, a bandwidth of the first sub-channel is shared by the first plurality of banks and the second plurality of banks in the second operating mode.

In a ninth aspect, in combination with one or more of the first aspect through the eighth aspect, the memory interface is configured to receive at least one bank-specific command comprising an indication of one of the first plurality of banks or the second plurality of banks for performing the bank-specific command.

In a tenth aspect, in combination with one or more of the first aspect through the ninth aspect, the bank-specific command comprises at least one of a bank activate command, a bank precharge command, a write command, a read command, or a refresh command.

In an eleventh aspect, in combination with one or more of the first aspect through the tenth aspect, the apparatus comprises a semiconductor die comprising the memory interface, the first plurality of banks, and the second plurality of banks.

In a twelfth aspect, in combination with one or more of the first aspect through the eleventh aspect, the memory interface is configured to communicate with the host device according to a low power double data rate (LPDDR) interface.

In a thirteenth aspect, in combination with one or more of the first aspect through the twelfth aspect, a method for operating a memory device, such as the apparatus defined in one or more of the first aspect through the twelfth aspect, includes communicating, by a memory module through a memory interface, first data stored in a first plurality of banks to a host device through a first sub-channel in a first operating mode; communicating, by the memory module through the memory interface, second data stored in a second plurality of banks to the host device through a second sub-channel in the first operating mode; receiving, by the memory module through the memory interface, a command to enter a second operating mode; and communicating, by the memory module through the memory interface, third data stored in the first plurality of banks and fourth data stored in the second plurality of banks to the host device through the first sub-channel in the second operating mode.

In a fourteenth aspect, in combination with one or more of the first aspect through the thirteenth aspect, receiving the command to enter the second operating mode comprises receiving a mode register write command setting a mode register of the memory interface to a value corresponding to the second operating mode.

In a fifteenth aspect, in combination with one or more of the first aspect through the fourteenth aspect, communicating the first data comprises communicating the first data through a first multiplexer configured to couple the first sub-channel to the first plurality of banks in the first operating mode, communicating the second data comprises communicating the second data through a second multiplexer configured to couple the second sub-channel to the second plurality of banks in the first operating mode, communicating the third data and the fourth data in the second operating mode comprises communicating the third data through the first multiplexer in the second operating mode, and communicating the fourth data comprises communicating the fourth data through the second multiplexer.

In a sixteenth aspect, in combination with one or more of the first aspect through the fifteenth aspect, the method further includes receiving control information from the first sub-channel, and controlling the first multiplexer and the second multiplexer by a mode register of the memory interface such that the first multiplexer couples the second plurality of banks to the first sub-channel based on the mode register and the control information.

In a seventeenth aspect, in combination with one or more of the first aspect through the sixteenth aspect, a bandwidth of the first sub-channel is shared by the first plurality of banks and the second plurality of banks in the second operating mode.

In an eighteenth aspect, in combination with one or more of the first aspect through the seventeenth aspect, the method further comprises receiving at least one bank-specific command comprising an indication of one of the first plurality of banks or the second plurality of banks for performing the bank-specific command.

In a nineteenth aspect, in combination with one or more of the first aspect through the eighteenth aspect, the bank-specific command comprises at least one of a bank activate command, a bank precharge command, a write command, a read command, or a refresh command.

In a twentieth aspect, in combination with one or more of the first aspect through the nineteenth aspect, an apparatus includes a memory controller with a first physical interface for communicating through a first sub-channel with a memory module and a second physical interface for communicating through a second sub-channel with the memory module, wherein the memory controller is configured to communicate with the memory interface of any of one or more of the first aspect through the nineteenth aspect, and the memory controller is configured to perform operations including communicating with the memory module through the first sub-channel and the second sub-channel in a first operating mode; providing a command for the memory module to enter a second operating mode; and communicating with the memory module only through the first sub-channel in the second operating mode.

In a twenty-first aspect, in combination with one or more of the first aspect through the twentieth aspect, the memory controller is further configured to perform operations of disabling the second physical interface in the second operating mode.

In a twenty-second aspect, in combination with one or more of the first aspect through the twenty-first aspect, to communicate with the memory module only through the first sub-channel in the second operating mode, the memory controller is further configured to transmit at least one bank-specific command comprising an operand indicating one of a first plurality of banks or a second plurality of banks of the memory module for performing the bank-specific command.

In a twenty-third aspect, in combination with one or more of the first aspect through the twenty-second aspect, disabling the second physical interface comprises disconnecting a supply voltage to the second physical interface.

In a twenty-fourth aspect, in combination with one or more of the first aspect through the twenty-third aspect, the apparatus comprises a semiconductor die comprising the memory controller; and at least one processor comprising at least one of a central processing unit (CPU) cluster, a graphics processing unit (GPU), an artificial intelligence (AI) engine, or a modem, wherein providing the command for the memory module to enter the second operating mode is performed based on a rule comprising one or more criteria based on a mode of operation of the at least one processor.

In a twenty-fifth aspect, in combination with one or more of the first aspect through the twenty-fourth aspect, the apparatus comprises a semiconductor die comprising the memory controller; and at least one processor comprising at least one of a central processing unit (CPU) cluster, a graphics processing unit (GPU), an artificial intelligence (AI) engine, or a modem, wherein the memory controller is configured to perform providing the command for the memory module to enter the second operating mode based on detecting a low-power mode of operation of the at least one processor.

In a twenty-sixth aspect, in combination with one or more of the first aspect through the twenty-fifth aspect, a method for operating a memory controller of a host device to communicate with the memory interface according to one or more aspects of the first aspect through the nineteenth aspect includes operations of communicating, by a host device, with a first plurality of banks of a memory module through a first sub-channel and with a second plurality of banks of the memory module through a second sub-channel in a first operating mode; providing, from the host device to the memory module, a command for the memory module to enter a second operating mode; and communicating, by the host device, with the first plurality of banks and the second plurality of banks only through the first sub-channel in the second operating mode.

In a twenty-seventh aspect, in combination with one or more of the first aspect through the twenty-sixth aspect, the method further includes disabling a physical interface of the host device corresponding to the second sub-channel in the second operating mode.

In a twenty-eighth aspect, in combination with one or more of the first aspect through the twenty-seventh aspect, providing the command for the memory module to enter the second operating mode comprises providing a mode register write command setting a mode register of the memory module to a value corresponding to the second operating mode.

In a twenty-ninth aspect, in combination with one or more of the first aspect through the twenty-eighth aspect, providing the command for the memory module to enter the second operating mode is performed based on a rule comprising one or more criteria based on a mode of operation of at least one processor of the host device.

In a thirtieth aspect, in combination with one or more of the first aspect through the twenty-ninth aspect, communicating, by the host device, with the first plurality of banks and the second plurality of banks only through the first sub-channel in the second operating mode comprises transmitting at least one bank-specific command comprising an operand indicating one of the first plurality of banks or the second plurality of banks of the memory module for performing the bank-specific command.

In the description of embodiments herein, numerous specific details are set forth, such as examples of specific components, circuits, and processes to provide a thorough understanding of the present disclosure. The term “coupled” as used herein means connected directly to or connected through one or more intervening components or circuits. Also, in the following description and for purposes of explanation, specific nomenclature is set forth to provide a thorough understanding of the present disclosure. However, it will be apparent to one skilled in the art that these specific details may not be required to practice the teachings disclosed herein. In other instances, well known circuits and devices are shown in block diagram form to avoid obscuring teachings of the present disclosure.

Some portions of the detailed descriptions which follow are presented in terms of procedures, logic blocks, processing, and other symbolic representations of operations on data bits within a computer memory. In the present disclosure, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system.

In the figures, a single block may be described as performing a function or functions. The function or functions performed by that block may be performed in a single component or across multiple components, and/or may be performed using hardware, software, or a combination of hardware and software. To clearly illustrate this interchangeability of hardware and software, various illustrative components, blocks, modules, circuits, and steps are described below generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the example devices may include components other than those shown, including well-known components such as a processor, memory, and the like.

Unless specifically stated otherwise as apparent from the following discussions, it is appreciated that throughout the present application, discussions utilizing the terms such as “accessing,” “receiving,” “sending,” “using,” “selecting,” “communicating,” “determining,” “normalizing,” “multiplying,” “averaging,” “monitoring,” “comparing,” “applying,” “updating,” “measuring,” “deriving,” “settling,” “generating,” or the like, refer to the actions and processes of a computer system, or similar electronic computing device, that manipulates and transforms data represented as physical (electronic) quantities within the computer system's registers and memories into other data similarly represented as physical quantities within the computer system's registers, memories, or other such information storage, transmission, or display devices.

The terms “device” and “apparatus” are not limited to one or a specific number of physical objects (such as one smartphone, one camera controller, one processing system, and so on). As used herein, a device may be any electronic device with one or more parts that may implement at least some portions of the disclosure. While the description and examples herein use the term “device” to describe various aspects of the disclosure, the term “device” is not limited to a specific configuration, type, or number of objects. As used herein, an apparatus may include a device or a portion of the device for performing the described operations.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Components, the functional blocks, and the modules described herein with respect to the Figures include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

Those of skill in the art that one or more blocks (or operations) described with reference to the figures included with this description may be combined with one or more blocks (or operations) described with reference to another of the figures. For example, one or more blocks (or operations) of FIG. 3A may be combined with one or more blocks of FIG. 2, FIG. 5, or FIG. 6. Likewise, one or more blocks (or operations) of FIG. 3B may be combined with one or more blocks of FIG. 2, FIG. 5, or FIG. 6.

Those of skill in the art would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Skilled artisans will also readily recognize that the order or combination of components, methods, or interactions that are described herein are merely examples and that the components, methods, or interactions of the various aspects of the present disclosure may be combined or performed in ways other than those illustrated and described herein.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits, and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single-or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, or any conventional processor, controller, microcontroller, or state machine. In some implementations, a processor may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, which is one or more modules of computer program instructions, encoded on a computer storage media for execution by, or to control the operation of, data processing apparatus.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that may be enabled to transfer a computer program from one place to another. A storage media may be any available media that may be accessed by a computer. By way of example, and not limitation, such computer-readable media may include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media.

Various modifications to the implementations described in this disclosure may be readily apparent to those skilled in the art, and the generic principles defined herein may be applied to some other implementations without departing from the scope of this disclosure. Thus, the claims are not intended to be limited to the implementations shown herein but are to be accorded the widest scope consistent with this disclosure, the principles and the novel features disclosed herein.

As used herein, the term “coupled to” in the various tenses of the verb “couple” may mean that element A is directly connected to element B or that other elements may be connected between elements A and B (i.e., that element A is indirectly connected with element B), to operate certain intended functions. In the case of electrical components, the term “coupled to” may also be used herein to mean that a wire, trace, or other electrically conductive material is used to electrically connect elements A and B (and any components electrically connected therebetween). In some examples, the term “coupled to” mean a transfer of electrical energy between elements A and B, to operate certain intended functions.

In some examples, the term “electrically connected” may mean having an electric current or configurable to having an electric current flowing between the elements A and B. For example, the elements A and B may be connected via resistors, transistors, or an inductor, in addition to a wire, trace, or other electrically conductive material and components. Furthermore, for radio frequency functions, the elements A and B may be “electrically connected” via a capacitor.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown, or in sequential order, or that all illustrated operations be performed to achieve desirable results. Further, the drawings may schematically depict one or more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof.

The term “substantially” is defined as largely, but not necessarily wholly, what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 1, 5, or 10 percent.

The previous description of the disclosure is provided to enable any person skilled in the art to make or use the disclosure. Various modifications to the disclosure will be readily apparent to those skilled in the art, and the generic principles defined herein may be applied to other variations without departing from the scope of the disclosure. Thus, the disclosure is not intended to be limited to the examples and designs described herein but is to be accorded the widest scope consistent with the principles and novel features disclosed herein.

What is claimed is:

1. An apparatus, comprising:
a memory interface coupled to a first plurality of banks and a second plurality of banks, the memory interface configured to couple the first plurality of banks and the second plurality of banks to a host device through a first sub-channel and a second sub-channel, and the memory interface configured to perform operations comprising:
communicating first data stored in the first plurality of banks to the host device through the first sub-channel in a first operating mode;
communicating second data stored in the second plurality of banks to the host device through the second sub-channel in the first operating mode;
receiving a command to enter a second operating mode; and
communicating third data stored in the first plurality of banks and fourth data stored in the second plurality of banks to the host device through the first sub-channel in the second operating mode.

2. The apparatus of claim 1, wherein the memory interface comprises:
a first multiplexer configured to couple the first sub-channel to the first plurality of banks in the first operating mode; and
a second multiplexer configured to couple the second sub-channel to the second plurality of banks in the first operating mode,
wherein the first multiplexer is further configured to couple the first sub-channel to the first plurality of banks or the second multiplexer in the second operating mode based at least in part on control information received from the first sub-channel, and
wherein the second multiplexer is further configured to couple the first multiplexer to the second plurality of banks in the second operating mode.

3. The apparatus of claim 2, wherein the memory interface further comprises control circuitry configured to control the first multiplexer and the second multiplexer such that the first multiplexer couples the second plurality of banks to the first sub-channel based on a mode register and the control information.

4. The apparatus of claim 3, wherein the control circuitry comprises a mode register configured to store a first value corresponding to the first operating mode or a second value corresponding to the second operating mode.

5. The apparatus of claim 4, wherein receiving the command to enter the second operating mode comprises receiving a mode register write command setting the mode register to the second value corresponding to the second operating mode.

6. The apparatus of claim 4, wherein the control circuitry further comprises logic circuitry configured to receive the control information and a stored value from the mode register for controlling the first multiplexer.

7. The apparatus of claim 2, wherein:
the first sub-channel comprises a first data bus, a first clock signal, and a first command and address bus, and
the second sub-channel comprises a second data bus, a second clock signal, and a second command and address bus,
wherein the control information is received from the first command and address bus.

8. The apparatus of claim 1, wherein a bandwidth of the first sub-channel is shared by the first plurality of banks and the second plurality of banks in the second operating mode.

9. The apparatus of claim 1, wherein the memory interface is configured to:
receive at least one bank-specific command comprising an indication of one of the first plurality of banks or the second plurality of banks for performing the bank-specific command.

10. The apparatus of claim 9, wherein the bank-specific command comprises at least one of a bank activate command, a bank precharge command, a write command, a read command, or a refresh command.

11. The apparatus of claim 1, wherein the apparatus comprises a semiconductor die comprising the memory interface, the first plurality of banks, and the second plurality of banks.

12. The apparatus of claim 11, wherein the memory interface is configured to communicate with the host device according to a low power double data rate (LPDDR) interface.

13. A method, comprising:
communicating, by a memory module through a memory interface, first data stored in a first plurality of banks to a host device through a first sub-channel in a first operating mode;
communicating, by the memory module through the memory interface, second data stored in a second plurality of banks to the host device through a second sub-channel in the first operating mode;
receiving, by the memory module through the memory interface, a command to enter a second operating mode; and
communicating, by the memory module through the memory interface, third data stored in the first plurality of banks and fourth data stored in the second plurality of banks to the host device through the first sub-channel in the second operating mode.

14. The method of claim 13, wherein receiving the command to enter the second operating mode comprises receiving a mode register write command setting a mode register of the memory interface to a value corresponding to the second operating mode.

15. The method of claim 13, wherein:
communicating the first data comprises communicating the first data through a first multiplexer configured to couple the first sub-channel to the first plurality of banks in the first operating mode;
communicating the second data comprises communicating the second data through a second multiplexer configured to couple the second sub-channel to the second plurality of banks in the first operating mode;
communicating the third data and the fourth data in the second operating mode comprises communicating the third data through the first multiplexer in the second operating mode; and
communicating the fourth data comprises communicating the fourth data through the second multiplexer.

16. The method of claim 15, further comprising:
receiving control information from the first sub-channel; and
controlling the first multiplexer and the second multiplexer by a mode register of the memory interface such that the first multiplexer couples the second plurality of banks to the first sub-channel based on the mode register and the control information.

17. The method of claim 13, wherein a bandwidth of the first sub-channel is shared by the first plurality of banks and the second plurality of banks in the second operating mode.

18. The method of claim 13, further comprising:
receiving at least one bank-specific command comprising an indication of one of the first plurality of banks or the second plurality of banks for performing the bank-specific command.

19. The method of claim 18, wherein the bank-specific command comprises at least one of a bank activate command, a bank precharge command, a write command, a read command, or a refresh command.

20. An apparatus, comprising:
a memory controller with a first physical interface for communicating through a first sub-channel with a memory module and a second physical interface for communicating through a second sub-channel with the memory module,
the memory controller configured to perform operations including:
communicating with the memory module through the first sub-channel and the second sub-channel in a first operating mode;
providing a command for the memory module to enter a second operating mode; and
communicating with the memory module only through the first sub-channel in the second operating mode.

21. The apparatus of claim 20, wherein the memory controller is further configured to perform operations of disabling the second physical interface in the second operating mode.

22. The apparatus of claim 21, wherein, to communicate with the memory module only through the first sub-channel in the second operating mode, the memory controller is further configured to transmit at least one bank-specific command comprising an operand indicating one of a first plurality of banks or a second plurality of banks of the memory module for performing the bank-specific command.

23. The apparatus of claim 20, wherein disabling the second physical interface comprises disconnecting a supply voltage to the second physical interface.

24. The apparatus of claim 20, wherein the apparatus comprises a semiconductor die comprising:
the memory controller; and
at least one processor comprising at least one of a central processing unit (CPU) cluster, a graphics processing unit (GPU), an artificial intelligence (AI) engine, or a modem, wherein providing the command for the memory module to enter the second operating mode is performed based on a rule comprising one or more criteria based on a mode of operation of the at least one processor.

25. The apparatus of claim 20, wherein the apparatus comprises a semiconductor die comprising:
the memory controller; and
at least one processor comprising at least one of a central processing unit (CPU) cluster, a graphics processing unit (GPU), an artificial intelligence (AI) engine, or a modem, wherein the memory controller is configured to perform providing the command for the memory module to enter the second operating mode based on detecting a low-power mode of operation of the at least one processor.

26. A method, comprising:
communicating, by a host device, with a first plurality of banks of a memory module through a first sub-channel and with a second plurality of banks of the memory module through a second sub-channel in a first operating mode;
providing, from the host device to the memory module, a command for the memory module to enter a second operating mode; and
communicating, by the host device, with the first plurality of banks and the second plurality of banks only through the first sub-channel in the second operating mode.

27. The method of claim 26, further comprising disabling a physical interface of the host device corresponding to the second sub-channel in the second operating mode.

28. The method of claim 27, wherein providing the command for the memory module to enter the second operating mode comprises providing a mode register write command setting a mode register of the memory module to a value corresponding to the second operating mode.

29. The method of claim 27, wherein providing the command for the memory module to enter the second operating mode is performed based on a rule comprising one or more criteria based on a mode of operation of at least one processor of the host device.

30. The method of claim 27, wherein communicating, by the host device, with the first plurality of banks and the second plurality of banks only through the first sub-channel in the second operating mode comprises transmitting at least one bank-specific command comprising an operand indicating one of the first plurality of banks or the second plurality of banks of the memory module for performing the bank-specific command.
